(19) United States
(12) Patent Application Publication
(10) Pub. No.: US 2025/0070203 A1
(43) Pub. Date: Feb. 27, 2025

(54) FUEL CELL SYSTEM, VEHICLE, AND METHOD OF MEASURING IMPEDANCE

(71) Applicant: SUBARU CORPORATION, Tokyo (JP)

(72) Inventor: Yushi FUKUTOMI, Tokyo (JP)

(21) Appl. No.: 18/944,514

(22) Filed: Nov. 12, 2024

Related U.S. Application Data
(63) Continuation of application No. PCT/JP2023/010290, filed on Mar. 16, 2023.

(51) Int. Cl. H01M 8/04537; B60L 50/75; G01R 31/00; G01R 31/389; H01M 8/04858; H01M 10/48; H01M 16/00

(52) U.S. Cl. CPC H01M 8/04641; B60L 50/75; G01R 31/006; G01R 31/389; H01M 8/04656; H01M 8/04932; H01M 8/04947; H01M 10/48; H01M 16/006; H01M 2220/20; H01M 2250/20

(57) ABSTRACT

A fuel cell system includes a fuel cell, a power storage, a single measuring unit, and a switcher. The power storage is configured to store electric power. The single measuring unit is configured to perform a measurement of an impedance of each of the fuel cell and the power storage. The switcher is configured to set each of a first coupling state between the single measuring unit and the fuel cell and a second coupling state between the single measuring unit and the power storage. The switcher is configured to set the first coupling state and the second coupling state in response to a state of the fuel cell system upon the measurement of the impedance by the single measuring unit. The state of the fuel cell system includes whether electric power is outputted from the fuel cell and whether the power storage is discharged or charged.

### CROSS-REFERENCE TO RELATED APPLICATIONS

This application is continuation of International Application No. PCT/JP2023/010290, filed on Mar. 16, 2023, the entire contents of which are hereby incorporated by reference.

### BACKGROUND

The disclosure relates to a fuel cell system including a fuel cell and a power storage, a vehicle including such a fuel cell system, and a method of measuring impedances of a fuel cell and a power storage.

Various techniques have been disclosed as a fuel cell system including a fuel cell and a power storage and a method of measuring impedances of, for example, a fuel cell and a power storage. For example, reference is made to Japanese Unexamined Patent Application Publication (Translation of PCT Application) No. 2005-538499.

### SUMMARY

An aspect of the disclosure provides a fuel cell system including a fuel cell, a power storage, a single measuring unit, and a switcher. The power storage is configured to store electric power. The single measuring unit is configured to perform a measurement of an impedance of each of the fuel cell and the power storage. The switcher is configured to set each of a first coupling state between the single measuring unit and the fuel cell and a second coupling state between the single measuring unit and the power storage. The switcher is configured to set the first coupling state and the second coupling state in response to a state of the fuel cell system upon the measurement of the impedance by the single measuring unit. The state of the fuel cell system includes whether electric power is outputted from the fuel cell and whether the power storage is discharged or charged.

An aspect of the disclosure provides a vehicle including a fuel cell system. The fuel cell system includes a fuel cell, a power storage, a single measuring unit, and a switcher. The power storage is configured to store electric power. The single measuring unit is configured to perform a measurement of an impedance of each of the fuel cell and the power storage. The switcher is configured to set each of a first coupling state between the single measuring unit and the fuel cell and a second coupling state between the single measuring unit and the power storage. The switcher is configured to set the first coupling state and the second coupling state in response to a state of the fuel cell system upon the measurement of the impedance by the single measuring unit. The state of the fuel cell system includes whether electric power is outputted from the fuel cell and whether the power storage is discharged or charged.

An aspect of the disclosure provides a method of measuring an impedance of each of a fuel cell and a power storage of a fuel cell system. The fuel cell system includes the fuel cell and the power storage configured to store electric power. The method includes: measuring, with a single measuring unit, the impedance of each of the fuel cell and the power storage; and setting each of a first coupling state between the single measuring unit and the fuel cell and a second coupling state between the single measuring unit and the power storage in response to a state of the fuel cell system upon the measuring the impedance with the single measuring unit. The state of the fuel cell system includes whether electric power is outputted from the fuel cell and whether the power storage is discharged or charged.

An aspect of the disclosure provides a fuel cell system including a fuel cell, a power storage, a single measuring unit, and circuitry. The power storage is configured to store electric power. The circuitry is configured to perform a measurement of an impedance of each of the fuel cell and the power storage, and set each of a first coupling state between the single measuring unit and the fuel cell and a second coupling state between the single measuring unit and the power storage. The circuitry is configured to set the first coupling state and the second coupling state in response to a state of the fuel cell system upon the measurement of the impedance by the single measuring unit. The state of the fuel cell system includes whether electric power is outputted from the fuel cell and whether the power storage is discharged or charged.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the disclosure.

FIG. 1 is a block diagram illustrating a schematic configuration example of a vehicle according to one example embodiment of the disclosure.

FIG. 2 is a block diagram illustrating a detailed configuration example of a fuel cell system illustrated in FIG. 1.

FIG. 3 is a diagram illustrating setting examples of a switching switch according to one example embodiment.

FIG. 4 is a block diagram schematically illustrating an operation example of the fuel cell system illustrated in FIG. 2.

FIG. 5 is a block diagram schematically illustrating another operation example of the fuel cell system illustrated in FIG. 2.

FIG. 6 is a diagram illustrating setting examples of the switching switch according to one modification example.

FIG. 7 is a diagram illustrating setting examples of the switching switch according to one modification example.

### DETAILED DESCRIPTION

In a fuel cell system including a fuel cell and a power storage, it is desired to measure impedances of the fuel cell and the power storage at low cost.

It is desirable to provide a fuel cell system, a vehicle, and a method of measuring an impedance that make it possible to measure impedances of a fuel cell and a power storage at low cost.

In the following, some example embodiments of the disclosure are described in detail with reference to the accompanying drawings. Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the disclosure are unillustrated in the drawings.

### Example Embodiment

### Schematic Configuration Example

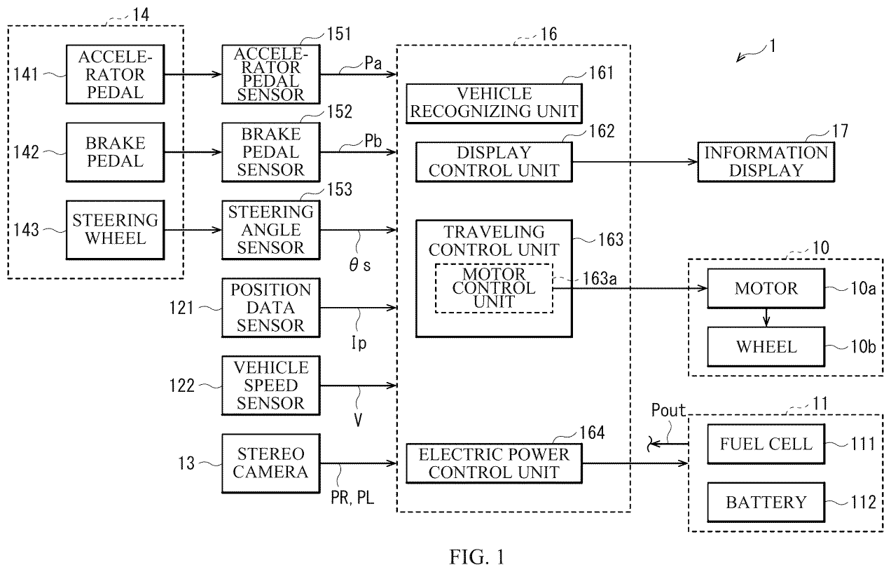

FIG. 1 illustrates, in a block diagram, a schematic configuration example of a vehicle (a vehicle 1) according to an example embodiment of the disclosure. The vehicle 1 is equipped with a fuel cell system 11 including a fuel cell 111 to be described later, and is configured as a fuel cell vehicle.

The vehicle 1 may include a drive mechanism 10, the fuel cell system 11, a position data sensor 121, a vehicle speed sensor 122, a stereo camera 13, an operation receiving unit 14, an accelerator pedal sensor 151, a brake pedal sensor 152, a steering angle sensor 153, a vehicle processor 16, and an information display 17. Note that a method of measuring an impedance according to an example embodiment of the disclosure is implemented by an operation (a process of measuring the impedance) in the fuel cell system 11 to be described later, and will be described together in the following.

### Drive Mechanism 10

The drive mechanism 10 may include a motor 10a and a wheel 10b. The motor 10a may be an electric motor. The motor 10a may generate driving torque of the vehicle 1, and the generated driving torque may be transmitted to the wheel 10b. The number of the wheels 10b may be, for example, four in a case of a four-wheel vehicle, or two in a case of a two-wheel vehicle.

### Fuel Cell System 11

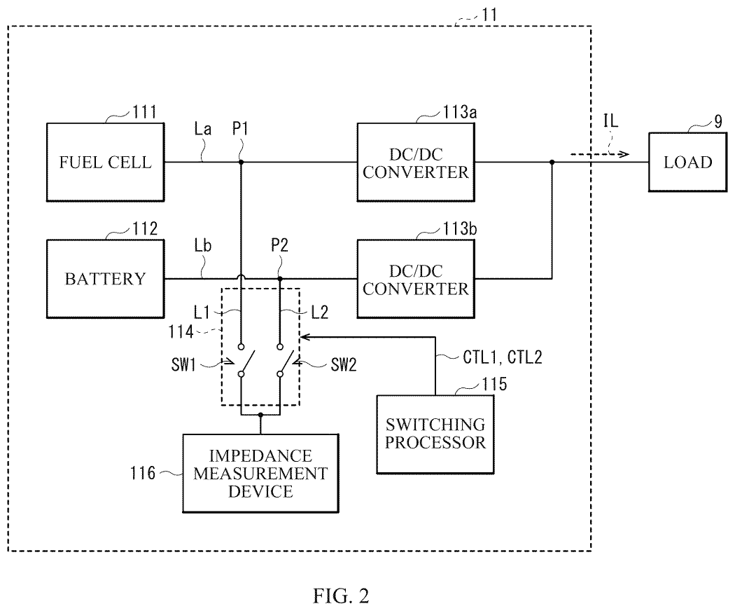

The fuel cell system 11 is a system including the fuel cell 111 and a battery 112. Electric power Pout that is outputted from the fuel cell system 11 may be supplied to the entire vehicle 1, as electric power of the vehicle 1. A detailed configuration example of the fuel cell system 11 will be described later (FIG. 2).

### Position data Sensor 121 and Vehicle Speed Sensor 122

The position data sensor 121 may be a sensor that acquires position data Ip of the vehicle 1. The position data sensor 121 may include, for example, a GPS sensor that acquires the position data Ip of the vehicle 1 by receiving satellite signals from global positioning system (GPS) satellites. As the position data sensor 121, for example, an antenna that receives a satellite signal from another satellite system that identifies the position of the vehicle 1 may be used, instead of the GPS sensor. The position data Ip thus acquired by the position data sensor 121 may be outputted to the vehicle processor 16 (e.g., a traveling control unit 163 to be described later).

The vehicle speed sensor 122 may be a sensor that detects a speed, i.e., a vehicle speed V, of the vehicle 1. The vehicle speed V detected by the vehicle speed sensor 122 may be outputted to the vehicle processor 16 (e.g., the traveling control unit 163 to be described later).

### Stereo Camera 13

The stereo camera 13 may be a device, i.e., an imaging device, that captures an image of a surrounding situation or a traveling environment of the vehicle 1 and detects the surrounding situation or the traveling environment. The stereo camera 13 may include, for example, two cameras of a right camera and a left camera.

The right camera and the left camera may each include, for example, a lens and an image sensor. For example, the right camera and the left camera may be disposed in the vicinity of an upper portion of a windshield of the vehicle 1, being separated away from each other by a predetermined distance along a width direction of the vehicle 1. The right camera and the left camera may perform imaging operations in a manner synchronized with each other. For example, the right camera may generate a captured image PR as a right image, and the left camera may generate a captured image PL as a left image. The captured images PR and PL thus obtained by the stereo camera 13 including the right camera and the left camera may each be outputted to the vehicle processor 16 (e.g., a vehicle recognizing unit 161 and the traveling control unit 163 to be described later).

### Information Display 17

The information display 17 may be a device that outputs or displays various kinds of information for an occupant of the vehicle 1. The occupant of the vehicle 1 may be, for example, a driver who drives the vehicle 1. The information display 17 may include, for example, a head-up display (HUD) or any other display.

### Operation Receiving Unit 14 and Various Sensors

The operation receiving unit 14 may include an accelerator pedal 141, a brake pedal 142, and a steering wheel 143, as illustrated in FIG. 1. Each of the members of the operation receiving unit 14, i.e., each of the accelerator pedal 141, the brake pedal 142, and the steering wheel 143, may receive an operation performed by the occupant, such as the driver, of the vehicle 1 at least through an electrical signal, i.e., by what is called a by-wire method.

The accelerator pedal sensor 151 may be a sensor that detects an amount of pressing of the accelerator pedal 141 by the driver of the vehicle 1, i.e., an accelerator position Pa. The brake pedal sensor 152 may be a sensor that detects an amount of pressing of the brake pedal 142 by the driver of the vehicle 1, i.e., a brake pressing amount Pb. The steering angle sensor 153 may be a sensor that detects an amount of an operation performed on the steering wheel 143 by the driver of the vehicle 1, i.e., a steering angle θs.

Each of the accelerator position Pa, the brake pressing amount Pb, and the steering angle θs detected by the accelerator pedal sensor 151, the brake pedal sensor 152, and the steering angle sensor 153, respectively, may be outputted to the vehicle processor 16 (e.g., the traveling control unit 163 to be described later).

### Vehicle Processor 16

The vehicle processor 16 may be a member, i.e., a control unit, that controls various operations of the vehicle 1, and performs various calculation processes. For example, the vehicle processor 16 may include one or more processors, i.e., a central processing unit (CPU), and one or more memories. The one or more processors may execute programs. The one or more memories may be communicably coupled to the one or more processors. The one or more memories may include, for example, a random-access memory (RAM) and a read-only memory (ROM). The RAM may temporarily hold processing data. The ROM may hold programs.

In the example illustrated in FIG. 1, the vehicle processor 16 may include the vehicle recognizing unit 161, a display control unit 162, the traveling control unit 163, and an electric power control unit 164.

The vehicle recognizing unit 161 may be a unit that recognizes another vehicle other than the vehicle 1 as an own vehicle, by performing a predetermined calculation process, such as an image recognition process, based on the captured images PR and PL each obtained by the stereo camera 13, i.e., obtained by the right camera and the left camera, respectively. For example, the vehicle recognizing unit 161 may recognize a preceding vehicle traveling in front of the vehicle 1 as the other vehicle.

The display control unit 162 may be a unit that controls a display operation, i.e., an operation of displaying various kinds of information, performed by the information display 17 (see FIG. 1).

The traveling control unit 163 may be a unit that controls a traveling operation of the vehicle 1. The traveling control unit 163 may perform a comprehensive control related to traveling of the vehicle 1. For example, the traveling control unit 163 may perform an automated driving control of the vehicle 1. The automated driving control may include an automatic control of a driving system, a braking system, and a steering system of the vehicle 1. In a predetermined case, the traveling control unit 163 may cause transition from an automated driving mode to a manual driving mode to be performed, in other words, shift a driving mode. The automated driving mode may be a driving mode in which the automated driving control is performed. The manual driving mode may be a driving mode in which manual driving based on the operation received by the operation receiving unit 14 is performed.

The traveling control unit 163 may include a motor control unit 163a in the example illustrated in FIG. 1. The motor control unit 163a may be a unit that controls various operations of the motor 10a (see FIG. 1). For example, the motor control unit 163a may control a driving operation of the wheel 10b performed by the motor 10a, a regenerative operation performed by the motor 10a, and any other operation.

The traveling control unit 163 may also control the traveling operation of the vehicle 1 based on, for example, a recognition result related to another vehicle obtained by the vehicle recognizing unit 161 described above. The recognition result related to the other vehicle may include, for example, an inter-vehicle distance between the vehicle 1 and the other vehicle. For example, the traveling control unit 163 may perform an automatic following control related to the other vehicle or a preceding vehicle, an automatic acceleration and deceleration control, or any other control by increasing and decreasing the inter-vehicle distance between the vehicle 1 and the other vehicle, the vehicle speed V described above, or any other factor. The automatic acceleration and deceleration control may refer to a control of automatic deceleration and automatic acceleration.

The electric power control unit 164 may be a unit that controls operations (e.g., power generation and charging) of the fuel cell system 11. For example, the electric power control unit 164 may control the power generation of the fuel cell 111 based on requested electric power of the motor 10a. For example, when the electric power generated by the fuel cell 111 exceeds the requested electric power described above, the electric power control unit 164 may charge the battery 112 with extra electric power of electric power outputted from a DC/DC converter 113a, i.e., a converter, to be described later. In contrast, for example, when the electric power generated by the fuel cell 111 is less than the requested electric power described above, the electric power control unit 164 may complement the insufficient electric power by electric power outputted by the battery 112. Further, the electric power control unit 164 may charge the battery 112 with regenerative electric power of the motor 10a, for example, at the time of deceleration of the vehicle 1.

### Detailed Configuration Example of Fuel Cell System 11

Next, the detailed configuration example of the above-described fuel cell system 11 will be described referring to FIG. 2. FIG. 2 illustrates, in a block diagram, the detailed configuration example of the fuel cell system 11 illustrated in FIG. 1, together with a load 9 of the fuel cell system 11. In FIG. 2, a load current IL that flows from the fuel cell system 11 or the fuel cell 111 to the load 9 is also indicated by a dashed-line arrow.

In the example of FIG. 2, the fuel cell system 11 may include the fuel cell 111 and the battery 112 described above, two DC/DC converters 113a and 113b, a switching switch 114, a switching processor 115, and an impedance measurement device 116. Examples of the load 9 described above may include the motor 10a described above, an inverter, and any other device. The inverter may be a device that converts direct-current electric power outputted from the DC/DC converters 113a and 113b to be described later into three-phase alternating-current electric power, and supplies the resulting electric power to the motor 10a.

In one embodiment, the battery 112 may serve as a “power storage”. In one embodiment, the switching switch 114 and the switching processor 115 may serve as a “switcher”. In one embodiment, the impedance measurement device 116 may serve as a “measuring unit”.

The fuel cell 111 may be configured as, for example, a solid polymer electrolyte fuel cell, and may have a stacked structure including multiple fuel cells stacked. Each fuel cell may include a hydrogen electrode and an oxygen electrode provided on respective opposite sides of an electrolyte membrane including an ion exchange membrane. On the hydrogen electrode and the oxygen electrode may be provided, for example, a membrane electrode assembly (MEA) provided with gas diffusion layers. Further, each fuel cell may include a pair of separators disposed to sandwich the MEA. Hydrogen gas may be supplied to a hydrogen gas flow channel provided for the hydrogen electrode, and air may be supplied to an air flow channel provided for the oxygen electrode. The hydrogen gas and the air thus supplied may electrochemically react with each other, which allows for power generation. Note that the electric power (direct-current electric power) generated by the fuel cell 111 may be outputted to the DC/DC converter 113a through a path La.

The battery 112 may be configured to store electric power (direct-current electric power) supplied from the fuel cell 111 through the DC/DC converters 113a and 113b and a path Lb. The battery 112 may include any of various secondary batteries such as, for example, a lithium-ion battery. The battery 112 may store, for example, the regenerative electric power supplied from the motor 10a, as well as the electric power, i.e., generated electric power, obtained by the power generation of the fuel cell 111.

The DC/DC converter 113a may be a device that converts the direct-current electric power outputted from the fuel cell 111 into direct-current electric power at a predetermined level and outputs the resulting electric power. The DC/DC converter 113b may be a device that converts each of direct-current electric power for charging the battery 112 and direct-current electric power resulting from discharging the battery 112 into direct-current electric power at a predetermined level, and outputs the resulting electric power. The DC/DC converters 113a and 113b may each include any of various switching circuits (e.g., a chopper circuit). The direct-current electric power thus subjected to level conversion and outputted from the DC/DC converter 113a may be stored in the battery 112 through the DC/DC converter 113b or supplied to the load 9. In addition, the direct-current electric power subjected to level conversion and outputted from the DC/DC converter 113b may be supplied to the load 9.

The switching switch 114 is configured to set each of a coupling state, i.e., a first coupling state, between the impedance measurement device 116 to be described later and the fuel cell 111, and a coupling state, i.e., a second coupling state, between the impedance measurement device 116 and the battery 112, in accordance with a control by the switching processor 115 to be described later.

In the example of FIG. 2, the switching switch 114 may include two switches SW1 and SW2, and an on (ON) state or a coupled state and an off (OFF) state or a cut-off state of each of the switches SW1 and SW2 may be set in accordance with the control by the switching processor 115.

The switch SW1 as a first switch may be disposed on a path L1 between the impedance measurement device 116 and a coupling point P1 on the path La. The path La may be a path between the fuel cell 111 and the DC/DC converter 113a. Accordingly, when the switch SW1 is set to the on state, the coupling state, i.e., the first coupling state, between the impedance measurement device 116 and the fuel cell 111 may be set to the on state or the coupled state. In contrast, when the switch SW1 is set to the off state, the coupling state, i.e., the first coupling state, between the impedance measurement device 116 and the fuel cell 111 may be set to the off state or the cut-off state.

The switch SW2 as a second switch may be disposed on a path L2 between the impedance measurement device 116 and a coupling point P2 on the path Lb. The path Lb may be a path between the battery 112 and the DC/DC converter 113b. Accordingly, when the switch SW2 is set to the on state, the coupling state, i.e., the second coupling state, between the impedance measurement device 116 and the battery 112 may be set to the on state or the coupled state. In contrast, when the switch SW2 is set to the off state, the coupling state, i.e., the second coupling state, between the impedance measurement device 116 and the battery 112 may be set to the off state or the cut-off state.

The switching processor 115 may be a unit that controls the state of the switching switch 114, i.e., the on state or the off state of each of the switches SW1 and SW2, by using control signals CTL1 and CTL2. For example, the switching processor 115 may set the on state or the off state of the switch SW1 (the coupling state between the impedance measurement device 116 and the fuel cell 111: the first coupling state) by using the control signal CTL1. The switching processor 115 may also set the on state or the off state of the switch SW2 (the coupling state between the impedance measurement device 116 and the battery 112: the second coupling state) by using the control signal CTL2.

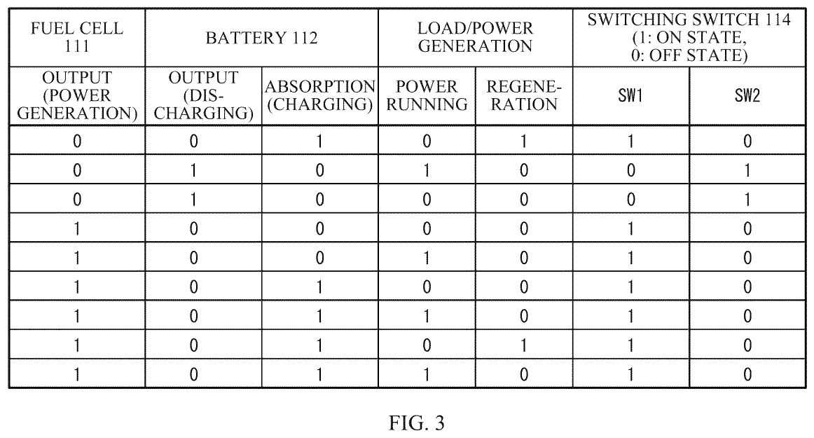

In the example embodiment, the switching processor 115 controls the state of the switching switch 114 in response to a state of the fuel cell system 11 upon measurement of the impedance by the impedance measurement device 116, to thereby set the first coupling state and the second coupling state described above. An operation of setting the first coupling state and the second coupling state in response to the state of the fuel cell system 11 will be described in detail later (FIGS. 3 to 5).

The switching processor 115 described above may include, for example, one or more processors, i.e., a CPU, and one or more memories. The one or more processors may execute programs. The one or more memories may be communicably coupled to the one or more processors. The one or more memories may include, for example, a RAM and a ROM. The RAM may temporarily hold processing data. The ROM may hold programs.

The impedance measurement device 116 is a device, i.e., a measuring unit, configured to measure each of an impedance Z1 as an internal impedance of the fuel cell 111 and an impedance Z2 as an internal impedance of the battery 112. In other words, the impedance measurement device 116 is configured as a single device or one device that measures each of the impedances Z1 and Z2 of the fuel cell 111 and the battery 112. Further, the impedance measurement device 116 may perform various calculation processes when measuring such impedances Z1 and Z2.

The impedance measurement device 116 described above may include, for example, one or more processors, i.e., a CPU, and one or more memories. The one or more processors may execute programs. The one or more memories may be communicably coupled to the one or more processors. The one or more memories may include, for example, a RAM and a ROM. The RAM may temporarily hold processing data. The ROM may hold programs.

The impedance measurement device 116 may measure the impedances Z1 and Z2 of the fuel cell 111 and the battery 112 by, for example, a predetermined frequency analysis. For example, the impedance measurement device 116 may use fast Fourier transform (FFT) analysis as an example of such a predetermined frequency analysis, and measure the impedances Z (=Z1 and Z2) of the fuel cell 111 and the battery 112 by an alternating-current impedance method in accordance with the following method in the order of steps A to E.
Step A: Coupling the load 9 to the fuel cell 111 or the battery 112, and outputting a direct current as the load current IL from the fuel cell 111 or the battery 112.
Step B: Superimposing an alternating-current component on the direct current.
Step C: Measuring a response (voltage and current characteristics) of the superimposed alternating-current component.
Step D: Calculating, by Fourier calculation, each of an absolute value |Z|, a real value X=ReZ (a value of a real part), and an imaginary value Y=ImZ (a value of an imaginary part) of the impedance Z at a specific frequency, as represented by the following expressions (a) to (c).
Step E: Creating what is called a “Cole-Cole plot”, which is a plot indicating correspondence between the real value X and the imaginary value Y of the impedance Z, based on analysis results at multiple frequencies of the superimposed alternating current.

$$\vert Z \vert = \vert Urms ( Uac ) \vert / \vert Irms ( Iac ) \vert \qquad ( a )$$

$$X = ( Urms ( Uac ) / Irms ( Iac ) ) \times cos φ \qquad ( b )$$

$$Y = ( Urms ( Uac ) / Irms ( Iac ) ) \times sin φ \qquad ( c )$$

Urms (Uac): Effective value of alternating-current voltage
Irms (Iac): Effective value of alternating current
φ: Phase difference between alternating-current voltage and alternating current

### Operations, Workings, and Example Effects

Next, operations, workings, and example effects of the example embodiment will be described in detail in comparison with a comparative example.

### A. Comparative Example

First, a vehicle equipped with a fuel cell typically uses a system, i.e., a fuel cell system, including the fuel cell and a battery in combination. An internal state of each of the fuel cell and the battery is detectable by measuring an impedance. An existing method (the comparative example) measures the impedance of the fuel cell and the impedance of the battery by individual methods or individual impedance measurement devices.

However, measuring the impedances by the method of the comparative example can complicate a configuration for the measurement of the impedances of the fuel cell and the battery. As a result, cost can increase for the measurement of the impedances of the fuel cell and the battery in the fuel cell system of the comparative example.

### B. Example of Operation of Setting Coupling States in Response to State of Fuel Cell System 11

Hence, in the fuel cell system 11 of the example embodiment, the single impedance measurement device 116 measures the impedances Z1 and Z2 of the fuel cell 111 and the battery 112. Upon the measurement of the impedances Z1 and Z2 by the impedance measurement device 116, the switching switch 114 and the switching processor 115 set the first coupling state and the second coupling state described above in response to the state of the fuel cell system 11. In other words, in the example embodiment, the single impedance measurement device 116 is switched to be coupled to both the fuel cell 111 and the battery 112, unlike the comparative example described above.

For example, in the example embodiment, the switching switch 114 and the switching processor 115 may set each of the coupling state, i.e., the first coupling state, between the impedance measurement device 116 and the fuel cell 111 and the coupling state, i.e., the second coupling state, between the impedance measurement device 116 and the battery 112 in response to a state of the fuel cell 111. An example of such an operation of setting the coupling states in response to the state of the fuel cell 111 is described in detail below.

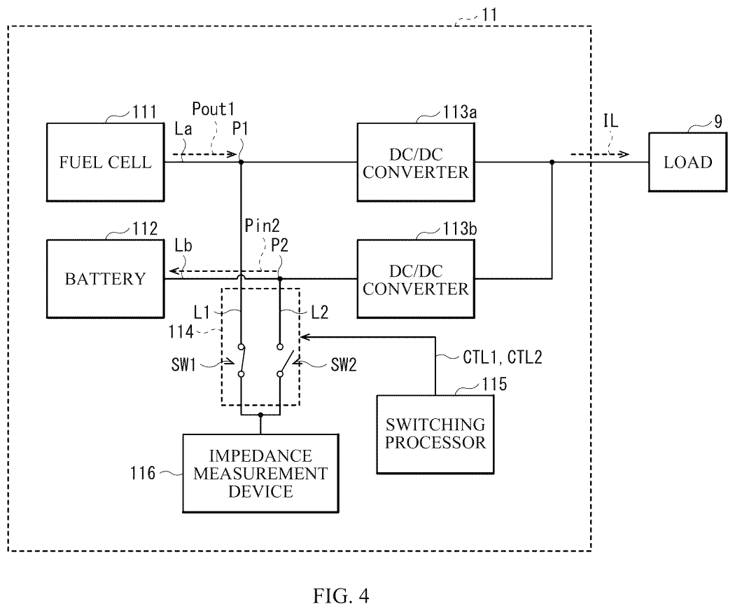

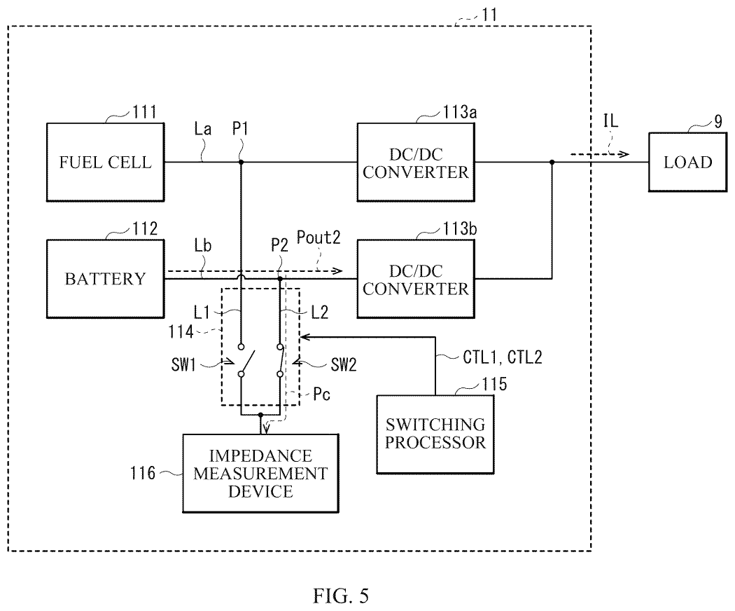

FIG. 3 illustrates, in a table, setting examples of the switching switch 114 including the switches SW1 and SW2 according to the example embodiment. For example, FIG. 3 illustrates an example of correspondence between the state of the fuel cell 111, a state of the battery 112, a state of (load/power generation), and a setting state of the switching switch 114 including the switches SW1 and SW2. FIGS. 4 and 5 each schematically illustrate, in a block diagram, an operation example of the fuel cell system 11 illustrated in FIG. 2.

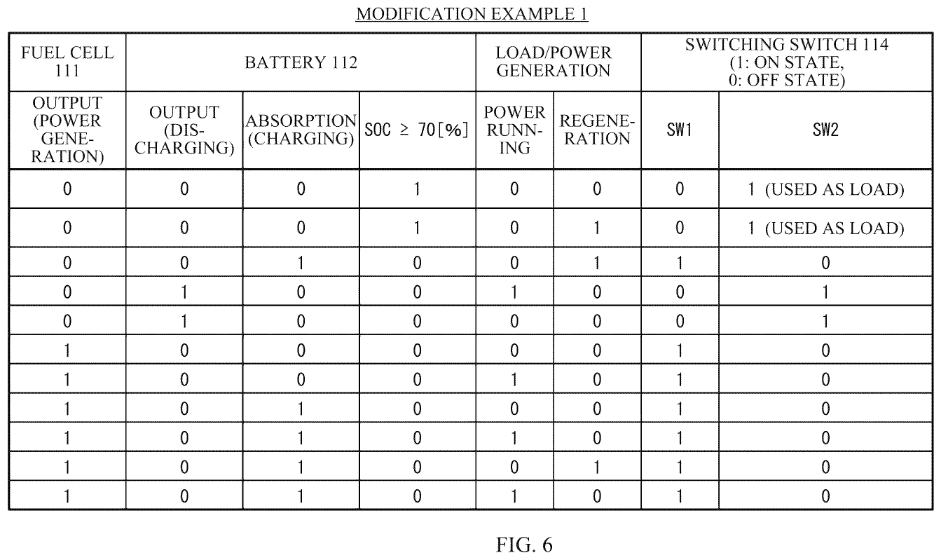

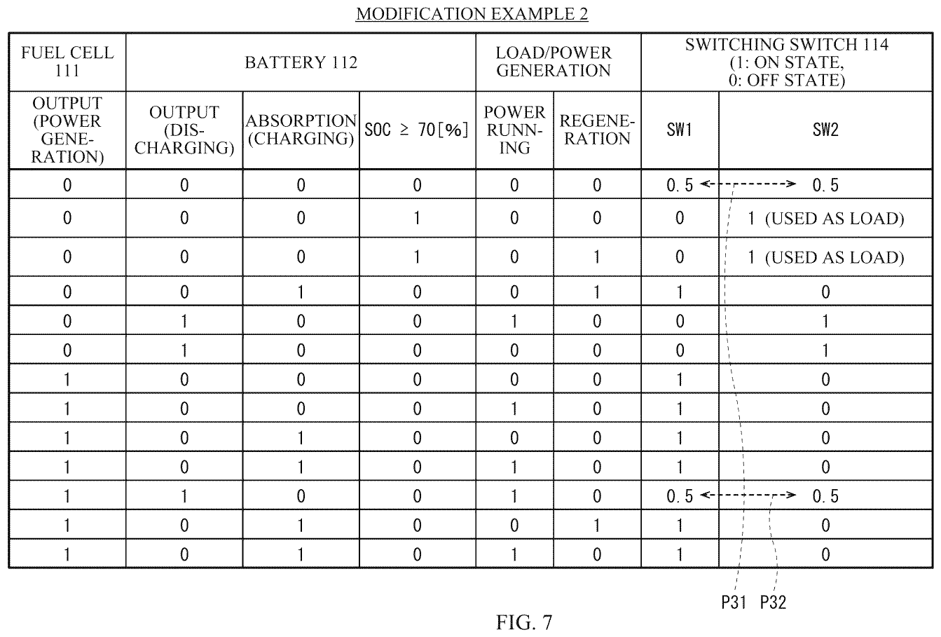

In the example of FIG. 3, regarding the state of the fuel cell 111, a state of output (power generation) of the fuel cell 111 is indicated as (“1”: outputting or generating power, “0”: not outputting or not generating power). Regarding the state of the battery 112, a state of output (discharging) of the battery 112 is indicated as (“1”: outputting or being discharged, “0”: not outputting or not being discharged), and a state of absorption (charging) of the battery 112 is indicated as (“1”: absorbing or being charged, “0”: not absorbing or not being charged). In addition, regarding the state of (load/power generation), a state of power running of the motor 10a included in the load 9 is indicated as (“1”: performing power running, “0”: not performing power running), and a state of regeneration of the motor 10a is indicated as (“1”: performing regeneration, “0”: not performing regeneration). The setting state of the switching switch 114 including the switches SW1 and SW2 is indicated as (“1”: ON (on) state, “0”: OFF (off) state). Note that these points similarly apply to cases of Modification Examples 1 and 2 to be described later (examples of FIGS. 6 and 7).

In the example embodiment, the switching switch 114 and the switching processor 115 may make the following settings in response to the state of the fuel cell 111, the state of the battery 112, and the state of (load/power generation).

First, when electric power is being outputted from the fuel cell 111 (when the output state of the fuel cell 111 is “1”, as represented by electric power Pout1 in FIG. 4), the switching switch 114 and the switching processor 115 may set the coupling state, i.e., the first coupling state, between the impedance measurement device 116 and the fuel cell 111 to the on state. For example, the switching processor 115 may set the first coupling state to the on state by setting the switch SW1 to the on state (the setting state of the switch SW1: “1”) by using the control signal CTL1 described above, as represented by the switch SW1 in FIG. 4.

When the battery 112 is being discharged (when the output state of the battery 112 is “1”, as represented by electric power Pout2 in FIG. 5), the switching switch 114 and the switching processor 115 may make the following setting. In this case, the switching switch 114 and the switching processor 115 may set the coupling state, i.e., the second coupling state, between the impedance measurement device 116 and the battery 112 to the on state. For example, the switching processor 115 may set the second coupling state to the on state by setting the switch SW2 to the on state (the setting state of the switch SW2: “1”) by using the control signal CTL2 described above, as represented by the switch SW2 in FIG. 5.

When the battery 112 is being charged (when the absorption state of the battery 112 is “1”, as represented by electric power Pin2 in FIG. 4), the switching switch 114 and the switching processor 115 may make the following setting. In this case, the switching switch 114 and the switching processor 115 may set the first coupling state described above to the on state, and set the second coupling state described above to the off state. For example, the switching processor 115 may set the switch SW1 to the on state (the setting state of the switch SW1: “1”) by using the control signal CTL1, and set the switch SW2 to the off state (the setting state of the switch SW2: “0”) by using the control signal CTL2, as represented by the switches SW1 and SW2 in FIG. 4. Thus, the first coupling state described above is set to the on state, and the second coupling state described above is set to the off state.

### C. Workings and Example Effects

As described above, in the fuel cell system 11 of the example embodiment, the following settings are made upon the measurement of the impedances Z1 and Z2 of the fuel cell 111 and the battery 112 by the single impedance measurement device 116. The coupling state, i.e., the first coupling state, between the impedance measurement device 116 and the fuel cell 111 and the coupling state, i.e., the second coupling state, between the impedance measurement device 116 and the battery 112 are each set in response to the state of the fuel cell system 11.

Thus, in the example embodiment, the following is achieved as compared with when the impedance Z1 of the fuel cell 111 and the impedance Z2 of the battery 112 are measured by individual methods or individual impedance measurement devices, for example, as in the comparative example described above. The example embodiment simplifies the configuration for the measurement of the impedances Z1 and Z2 of the fuel cell 111 and the battery 112 as compared with, for example, the comparative example described above. As a result, the example embodiment makes it possible to measure the impedances Z1 and Z2 of the fuel cell 111 and the battery 112 at low cost as compared with, for example, the comparative example described above.

Further, in some embodiments, the first coupling state described above may be set to the on state when electric power is being outputted from the fuel cell 111, and the second coupling state described above may be set to the on state when the battery 112 is being discharged. This makes it possible to measure the impedance Z1 of the fuel cell 111 when electric power is being outputted from the fuel cell 111, and to measure the impedance Z2 of the battery 112 when the battery 112 is being discharged. This easily allows for the measurement of the impedances Z1 and Z2 by the single impedance measurement device 116.

Further, in some embodiments, when the battery 112 is being charged, the first coupling state described above may be set to the on state and the second coupling state described above may be set to the off state. This makes it possible to measure the impedance Z1 of the fuel cell 111 in parallel with the charging of the battery 112, allowing for efficient impedance measurement.

### Modification Examples

Next, modification examples (Modification Examples 1 and 2) of the above-described example embodiment will be described. In the following, the same components as those in the example embodiment will be denoted by the same reference numerals, and description will be omitted as appropriate.

### Modification Example 1

### Configuration and Operation

FIG. 6 illustrates, in a table, setting examples of the switching switch 114 including the switches SW1 and SW2 according to Modification Example 1. The setting examples of the switching switch 114 in Modification Example 1 may additionally include, in the setting examples of the switching switch 114 in the example embodiment (FIG. 3), a state related to a state of charge (SOC) of the battery 112 as the state of the battery 112, and other setting examples may be similar.

In FIG. 6, when the state of charge (SOC) of the battery 112 is equal to or greater than a predetermined threshold (70[%] in the example of FIG. 6), i.e., when the battery 112 is in an overcharged state, the state related to the state of charge of the battery 112 is indicated as “1”. In contrast, when the state of charge (SOC) of the battery 112 is less than the threshold described above, i.e., when the battery 112 is not in the overcharged state, the state related to the state of charge of the battery 112 is indicated as “0”. Note that these points similarly apply to the case of Modification Example 2 to be described later (the example of FIG. 7).

In Modification Example 1, when the state of charge (SOC) of the battery 112 is equal to or greater than the threshold described above, i.e., when the state related to the state of charge described above is “1”, the switching switch 114 and the switching processor 115 may set the coupling state, i.e., the second coupling state, between the impedance measurement device 116 and the battery 112 to the on state. For example, the switching processor 115 may set the second coupling state to the on state by setting the switch SW2 to the on state (the setting state of the switch SW2: “1”) by using the control signal CTL2 described above, as represented by the switch SW2 in FIG. 5.

Further, when the state of charge of the battery 112 is thus equal to or greater than the threshold described above, i.e., when the battery 112 is in the overcharged state, the switching switch 114 and the switching processor 115 may set the second coupling state described above to the on state to thereby allow the impedance measurement device 116 to be used as follows. The switching switch 114 and the switching processor 115 may allow the impedance measurement device 116 to be used also as a load for electric power consumption (see electric power Pc in FIG. 5) when the battery 112 is discharged (see the electric power Pout2 in FIG. 5).

A reason for this is that, although electric power is typically consumed by using a driving unit such as a compressor to prevent the overcharged state of a battery included in a fuel cell system, this method can generate noise or operating sound upon the electric power consumption. Accordingly, in Modification Example 1, when the battery 112 is in the overcharged state, the impedance measurement device 116 may be used also as a load for electric power consumption, to thereby avoid noise that can be generated upon preventing the overcharged state of the battery 112 by the method described above.

### Workings and Example Effects

Also in Modification Example 1 described above, basically, workings similar to those in the example embodiment make it possible to achieve example effects similar to those in the example embodiment. In other words, Modification Example 1 also makes it possible to measure the impedances Z1 and Z2 of the fuel cell 111 and the battery 112 at low cost.

For example, in Modification Example 1, when the state of charge (SOC) of the battery 112 is equal to or greater than the predetermined threshold (e.g., 70[%]), the second coupling state described above may be set to the on state. This makes it possible to control the second coupling state in response to the state of charge of the battery 112, in addition to whether the battery 112 is being charged or being discharged, which allows for a variety of controls in the impedance measurement.

Further, in Modification Example 1, when the state of charge of the battery 112 is equal to or greater than the threshold, the second coupling state described above may be set to the on state, to thereby allow the impedance measurement device 116 to be used also as a load for electric power consumption at the time when the battery 112 is being discharged. This makes it possible to avoid the above-described noise that can be generated upon preventing the overcharged state of the battery 112, making it possible to improve convenience of the fuel cell system 11.

### Modification Example 2

### Configuration and Operation

FIG. 7 illustrates, in a table, setting examples of the switching switch 114 including the switches SW1 and SW2 according to Modification Example 2. The setting examples of the switching switch 114 in Modification Example 2 may additionally include, in the setting examples of the switching switch 114 in Modification Example 1 (FIG. 6), a case where both the first coupling state and the second coupling state described above are set to the on state as described below, and other setting examples may be similar.

In Modification Example 2, when setting both the first coupling state and the second coupling state described above to the on state in response to the state of the fuel cell system 11, the switching switch 114 and the switching processor 115 may alternately set the first coupling state and the second coupling state to the on state. For example, the switching processor 115 may alternately set the first coupling state and the second coupling state to the on state by alternately setting the switches SW1 and SW2 to the on state by using the control signals CTL1 and CTL2 described above (see dashed-line arrows P31 and P32 in FIG. 7).

In the example of FIG. 7, a case where the switches SW1 and SW2 are thus alternately set to the on state is represented by a time ratio, i.e., a duty ratio, between the on states of the switches SW1 and SW2. In other words, in the example of FIG. 7, the time ratio between the on states of the switches SW1 and SW2 may be set to 0.5 (50%) each. However, the time ratio between the on states of the switches SW1 and SW2 is not limited to the equal ratio of 0.5 (50%) each, and may be set to another time ratio. For example, the time ratio of the on state of one of the switches SW1 and SW2 may be set to be greater than the time ratio of the on state of the other.

For example, in the example of FIG. 7, both the first coupling state and the second coupling state described above may be set to the on state, and the first coupling state and the second coupling state (the switches SW1 and SW2) may be alternately set to the on state, in the following cases.
The fuel cell 111: a not-outputting state (a state indicating “0”); the battery 112: a not-outputting state (a state indicating “0”), a not-absorbing state (a state indicating “0”), and a (SOC <70%) state (a state indicating “0”); and a state where neither power running nor regeneration is being performed (a state indicating “0” and “0”). This case is represented by the dashed-line arrow P31 in FIG. 7.
The fuel cell 111: an outputting state (a state indicating “1”); the battery 112: an outputting state (a state indicating “1”), a not-absorbing state (a state indicating “0”), and a (SOC<70%) state (a state indicating “0”); and a state where power running is being performed and regeneration is not being performed (a state indicating “1” and “0”). This case is represented by the dashed-line arrow P32 in FIG. 7.

### Workings and Example Effects

Also in Modification Example 2 described above, basically, workings similar to those in the example embodiment make it possible to achieve example effects similar to those in the example embodiment. In other words, Modification Example 2 also makes it possible to measure the impedances Z1 and Z2 of the fuel cell 111 and the battery 112 at low cost.

For example, in Modification Example 2, when both the first coupling state and the second coupling state described above are set to the on state in response to the state of the fuel cell system 11, the first coupling state and the second coupling state may be alternately set to the on state. This makes it possible to perform a time-division control for the first coupling state and the second coupling state to control both the coupling states in parallel, which allows for a variety of controls in the impedance measurement.

Note that Modification Example 2 describes an example in a case of alternately setting the first coupling state and the second coupling state to the on state as described above in the setting examples of the switching switch 114 in Modification Example 1 (FIG. 6), but the disclosure is not limited to the example in this case. For example, the first coupling state and the second coupling state may be alternately set to the on state as described above in the setting examples of the switching switch 114 in the example embodiment (FIG. 3).

### Other Modification Examples

Although some example embodiments and modification examples of the disclosure have been described in the foregoing by way of example with reference to the accompanying drawings, the disclosure is by no means limited to the example embodiments and the modification examples described above. It should be appreciated that modifications and alterations may be made by persons skilled in the art without departing from the scope as defined by the appended claims. The disclosure is intended to include such modifications and alterations in so far as they fall within the scope of the appended claims or the equivalents thereof.

For example, the configurations (e.g., types, arrangements, or the numbers of pieces) of the respective members of the vehicle 1, the operation receiving unit 14, the vehicle processor 16, the fuel cell system 11, and any other component are not limited to those described in the example embodiments and the modification examples described above. Regarding the respective configurations of the above-described members, types, arrangements, the numbers of pieces, etc. other than those described may be employed. For example, in the example embodiments and the modification examples described above, a case where one motor (the motor 10a) is provided in the vehicle 1 has been described as an example, but the disclosure is not limited to this example. For example, multiple motors, i.e., two or more motors, may be provided in the vehicle 1. In addition, in the example embodiments and the modification examples described above, specific configuration examples of the switcher (configuration examples of the switching switch 114 and the switching processor 115) have been described, but these configuration examples are non-limiting, and another configuration example may be employed. Further, values, ranges, magnitude relationships, etc., of the various parameters described in the example embodiments and the modification examples described above are non-limiting. Other values, ranges, magnitude relationships, etc. may be employed.

For example, although in the example embodiments and the modification examples described above, specific examples have been described in relation to various processes (e.g., the process of setting the switching switch 114) to be performed by the vehicle 1, the vehicle processor 16, and the fuel cell system 11, the processes are not limited to the above-described specific examples. The various processes (e.g., the process of setting the switching switch 114) may be performed by any other method. In addition, configuration examples of the table to be used in the process of setting the switching switch 114, including the tables illustrated in FIGS. 3, 6, and 7, are non-limiting, and another configuration example may be employed.

Further, the series of processes described in the example embodiments and the modification examples described above may be performed by hardware such as a circuit, software such as a program, or a combination of hardware and software. When the processes are performed by software, the software may include a group of programs that causes a computer to execute respective operations. Each of the programs may be incorporated in the computer in advance, or may be installed on the computer via a network or a recording medium.

In addition, in the example embodiments and the modification examples described above, the fuel cell system to be applied to a vehicle has been described as an example, but the disclosure is not limited to this example. For example, the fuel cell system according to an example embodiment of the disclosure may be applied to other devices and systems other than a vehicle.

The various examples described above may be applied in any combination.

The example effects described herein are mere examples, and example effects of the disclosure are not limited to those described herein. Accordingly, the disclosure may achieve any other example effect.

The disclosure may also encompass at least the following embodiments.
(1) A fuel cell system including:
   a fuel cell;
   a power storage configured to store electric power;
   a single measuring unit configured to measure an impedance of each of the fuel cell and the power storage; and
   a switcher configured to set each of a first coupling state between the measuring unit and the fuel cell and a second coupling state between the measuring unit and the power storage, in which
   the switcher is configured to set the first coupling state and the second coupling state in response to a state of the fuel cell system upon the measurement of the impedance by the measuring unit, the state of the fuel cell system including whether electric power is outputted from the fuel cell and whether the power storage is discharged or charged.
(2) The fuel cell system according to (1), in which the switcher is configured to
   set the first coupling state to an on state when the electric power is being outputted from the fuel cell, and
   set the second coupling state to the on state when the power storage is being discharged.
(3) The fuel cell system according to (1) or (2), in which the switcher is configured to set the first coupling state to an on state and set the second coupling state to an off state, when the power storage is being charged.
(4) The fuel cell system according to any one of (1) to (3), in which the switcher is configured to set the second coupling state to an on state when a state of charge (SOC) of the power storage is equal to or greater than a threshold.
(5) The fuel cell system according to (4), in which the switcher is configured to set the second coupling state to the on state when the state of charge of the power storage is equal to or greater than the threshold, to thereby allow the measuring unit to be used also as a load for electric power consumption when the power storage is discharged.
(6) The fuel cell system according to any one of (1) to (5), in which, when setting both the first coupling state and the second coupling state to an on state in response to the state of the fuel cell system, the switcher is configured to alternately set the first coupling state and the second coupling state to the on state.
(7) A vehicle including a fuel cell system,
   the fuel cell system including:
   a fuel cell;
   a power storage configured to store electric power;
   a single measuring unit configured to measure an impedance of each of the fuel cell and the power storage; and
   a switcher configured to set each of a first coupling state between the measuring unit and the fuel cell and a second coupling state between the measuring unit and the power storage, in which
   the switcher is configured to set the first coupling state and the second coupling state in response to a state of the fuel cell system upon the measurement of the impedance by the measuring unit, the state of the fuel cell system including whether electric power is outputted from the fuel cell and whether the power storage is discharged or charged.
(8) A method of measuring an impedance of each of a fuel cell and a power storage of a fuel cell system, the fuel cell system including the fuel cell and the power storage configured to store electric power, the method including:
   measuring, with a single measuring unit, the impedance of each of the fuel cell and the power storage; and
   setting each of a first coupling state between the measuring unit and the fuel cell and a second coupling state between the measuring unit and the power storage in response to a state of the fuel cell system upon the measuring the impedance with the measuring unit, the state of the fuel cell system including whether electric power is outputted from the fuel cell and whether the power storage is discharged or charged.

Each of the vehicle processor 16 illustrated in FIG. 1 and the switching processor 115 and the impedance measurement device 116 illustrated in FIG. 2 is implementable by circuitry including at least one semiconductor integrated circuit such as at least one processor (e.g., a central processing unit (CPU)), at least one application specific integrated circuit (ASIC), and/or at least one field programmable gate array (FPGA). At least one processor is configurable, by reading instructions from at least one machine readable non-transitory tangible medium, to perform all or a part of functions of each of the vehicle processor 16 illustrated in FIG. 1 and the switching processor 115 and the impedance measurement device 116 illustrated in FIG. 2. Such a medium may take many forms, including, but not limited to, any type of magnetic medium such as a hard disk, any type of optical medium such as a CD and a DVD, any type of semiconductor memory (i.e., semiconductor circuit) such as a volatile memory and a non-volatile memory. The volatile memory may include a DRAM and a SRAM, and the nonvolatile memory may include a ROM and a NVRAM. The ASIC is an integrated circuit (IC) customized to perform, and the FPGA is an integrated circuit designed to be configured after manufacturing in order to perform, all or a part of the functions of each of the vehicle processor 16 illustrated in FIG. 1 and the switching processor 115 and the impedance measurement device 116 illustrated in FIG. 2.

1. A fuel cell system comprising:
a fuel cell;
a power storage configured to store electric power;
a single measuring unit configured to perform a measurement of an impedance of each of the fuel cell and the power storage; and
a switcher configured to set each of a first coupling state between the single measuring unit and the fuel cell and a second coupling state between the single measuring unit and the power storage, wherein
the switcher is configured to set the first coupling state and the second coupling state in response to a state of the fuel cell system upon the measurement of the impedance by the single measuring unit, the state of the fuel cell system comprising whether electric power is outputted from the fuel cell and whether the power storage is discharged or charged.

2. The fuel cell system according to claim 1, wherein the switcher is configured to
set the first coupling state to an on state when the electric power is being outputted from the fuel cell, and
set the second coupling state to an on state when the power storage is being discharged.

3. The fuel cell system according to claim 1, wherein the switcher is configured to set the first coupling state to an on state and set the second coupling state to an off state, when the power storage is being charged.

4. The fuel cell system according to claim 2, wherein the switcher is configured to set the first coupling state to the on state and set the second coupling state to an off state, when the power storage is being charged.

5. A vehicle comprising a fuel cell system,
the fuel cell system comprising:
a fuel cell;
a power storage configured to store electric power;
a single measuring unit configured to perform a measurement of an impedance of each of the fuel cell and the power storage; and
a switcher configured to set each of a first coupling state between the single measuring unit and the fuel cell and a second coupling state between the single measuring unit and the power storage, wherein
the switcher is configured to set the first coupling state and the second coupling state in response to a state of the fuel cell system upon the measurement of the impedance by the single measuring unit, the state of the fuel cell system comprising whether electric power is outputted from the fuel cell and whether the power storage is discharged or charged.

6. A method of measuring an impedance of each of a fuel cell and a power storage of a fuel cell system, the fuel cell system comprising the fuel cell and the power storage configured to store electric power, the method comprising:
measuring, with a single measuring unit, the impedance of each of the fuel cell and the power storage; and
setting each of a first coupling state between the single measuring unit and the fuel cell and a second coupling state between the single measuring unit and the power storage in response to a state of the fuel cell system upon the measuring the impedance with the single measuring unit, the state of the fuel cell system comprising whether electric power is outputted from the fuel cell and whether the power storage is discharged or charged.

7. A fuel cell system comprising:
a fuel cell;
a power storage configured to store electric power; and
circuitry configured to
perform a measurement of an impedance of each of the fuel cell and the power storage; and
set each of a first coupling state between the single measuring unit and the fuel cell and a second coupling state between the single measuring unit and the power storage, wherein
the circuitry is configured to set the first coupling state and the second coupling state in response to a state of the fuel cell system upon the measurement of the impedance by the single measuring unit, the state of the fuel cell system comprising whether electric power is outputted from the fuel cell and whether the power storage is discharged or charged.
